(19) United States
(12) Patent Application Publication
(10) Pub. No.: US 2016/0093546 A1
(43) Pub. Date: Mar. 31, 2016

(54) PACKAGE STUCTURE AND METHOD OF FABRICATING THE SAME

(71) Applicant: Siliconware Precision Industries Co., Ltd., Taichung (TW)

(72) Inventors: Yu-Cheng Pai, Taichung (TW); Shih-Chao Chiu, Taichung (TW); Chun-Hsien Lin, Taichung (TW); Chih-Wen Fan, Taichung (TW); Cheng-Chia Chen, Taichung (TW)

(21) Appl. No.: 14/833,102

(22) Filed: Aug. 23, 2015

(30) Foreign Application Priority Data
Sep. 26, 2014 (TW) 103133456
Jul. 27, 2015 (TW) 104124217

(51) Int. Cl. H01L 23/13; H01L 21/56; H01L 23/00; H01L 21/48

(52) U.S. Cl. CPC H01L 23/13; H01L 21/481; H01L 21/563; H01L 24/83

(57) ABSTRACT

A method of fabricating a package structure is provided. The method includes providing a carrier having two opposing surfaces, forming dielectric bodies on the two surfaces of the carrier, respectively, each of the dielectric bodies having a wiring layer embedded therein and a conductive layer formed on the wiring layer, and removing the carrier. Therefore, the wiring layers, the conductive layers and the dielectric bodies are formed on the two surfaces of the carrier, respectively, and the production yield is thus increased. The present invention further provides the package structure thus fabricated.

### BACKGROUND OF THE INVENTION

1. Field of the Invention

The present invention relates to package structures, and, more particularly, to a circuit package structure of a semiconductor package and a method of fabricating the same.

2. Description of Related Art

With the rapid growth in electronic industry, high-end electronic products have been developed to have a compact size and a low profile. As the packaging technology advances, an increasing number of different types of chip packaging technologies have been developed, as well as the size of the semiconductor package is continuously decreasing in order to achieve the low-profile requirement for the semiconductor package.

FIGS. 1A-1C are cross-sectional views showing a method of fabricating a conventional package structure 1.

As shown in FIG. 1A, a dielectric body 11 is formed on a carrier, and a wiring layer 12 and a conductive layer 13 formed on the wiring layer 12 are embedded in the dielectric body 11. Subsequently, a portion of the carrier is removed, with the remaining carrier serving as a supporting board 10. An electronic component 14 is disposed on the dielectric body 11, and electrically connected to the wiring layer 12 via a plurality of conductive elements 140 such as solder materials or copper pillars.

As shown in FIG. 1B, the foregoing structure is disposed in a mold 90.

As shown in FIG. 1C, a cavity 900 of the mold 90 is filled with an encapsulant 15, and then the mold 90 and the supporting board 10 are removed.

However, in the method of fabricating the conventional package structure 1 since the carrier also serves as a supporting board 10, the package structure 1 can only be formed on one side of the carrier, leading to a low production yield (units per hour, UPH).

Moreover, since the supporting board 10 abuts against the mold 90, a gap exists between the mold 90 and the dielectric body 11. Therefore, the minimum thickness of the encapsulant 15 is equal to the height h of the supporting board 10. The encapsulant 15 is required to have a thickness h′ greater than or equal to the height h of the supporting board 10 (that is the original thickness of the carrier). Hence, it is not possible to have a thinner encapsulant 15, and it is difficult for the conventional package structure 1 to satisfy the low-profile requirement.

Accordingly, there is an urgent need for solving the foregoing prior art problems.

### SUMMARY OF THE INVENTION

In view of the foregoing drawbacks, the present invention provides a package structure, comprising: a carrier having two opposing surfaces; and two dielectric bodies formed on the two surfaces of the carrier, respectively, each of the dielectric bodies having a first wiring layer embedded therein and a first conductive layer formed on the first wiring layer.

The present invention further provides a method of fabricating a package structure, comprising: providing a carrier having two opposing surfaces; forming dielectric bodies on the two surfaces of the carrier, respectively, each of the dielectric bodies having a first wiring layer embedded therein and a first conductive layer formed on the first wiring layer; and removing the carrier.

In an embodiment, the method further comprises: disposing an electronic component on the dielectric bodies, and electrically connecting the electronic component to the first wiring layers; forming on the dielectric bodies an encapsulant that encapsulates the electronic component; and filling an underfill into the space between the dielectric bodies and the electronic component in order to securely fix the electronic component in position.

In an embodiment, the two surfaces of the carrier are metal surfaces.

In an embodiment, the first wiring layers are formed on the two surfaces of the carrier and coupled to the carrier, the first conductive layers are formed on a portion of the two surfaces of the first wiring layers, and the dielectric bodies are then formed on the two surfaces of the carrier. In another embodiment, the first wiring layers are formed on the two surfaces of the carrier through a first photosensitive dielectric layer, and then the first conductive layers are formed on a portion of the surfaces of the first wiring layers through a second photosensitive dielectric layer, with the first and second photosensitive dielectric layers serving as the dielectric bodies.

In an embodiment, the first conductive layers are exposed from the dielectric bodies. In another embodiment, the dielectric bodies are formed on the two surfaces of the carrier, with the first conductive layers free from being exposed from the two surfaces of the dielectric body, and a portion of the surfaces of the dielectric bodies is removed, with the first conductive layers exposed from the dielectric bodies.

In an embodiment, the dielectric bodies are made of a molding compound, a prepreg, or a photosensitive dielectric layer.

In an embodiment, second wiring layers are further formed on the dielectric bodies, and electrically connected to the first conductive layers.

In an embodiment, insulation protection layers are further formed on the dielectric bodies and the second wiring layers.

In an embodiment, second conductive layers are further formed on the second wiring layers, and dielectric layers are formed on the dielectric bodies and encapsulate the second wiring layers and the second conductive layers. Further, third wiring layers are formed on the dielectric layers, and electrically connected to the second conductive layers. Still further, insulation protection layers are formed on the dielectric layers and the third wiring layers.

In summary, the package structure and the method of fabricating the package structure according to the present invention are characterized by forming wiring layers, conductive layers and dielectric bodies independently on two opposing surfaces of the carrier, as compared to the prior art, which forms these components on only one side of the carrier. Hence, the production yield of the package structure thus fabricated is increased by two fold, as compared to the prior art.

Moreover, the carrier is removed to prevent the need of forming a conventional supporting board, such that the cavity of the mold can be reduced according to practical needs when forming the encapsulant, thereby greatly reducing the structural height of the package and satisfying the low-profile requirement for electronic products.

In a method according to the present invention, the wiring layers and the conductive layers are formed first, the dielectric bodies are then formed, and then the conductive layers are exposed to be electrically connected to circuits that are to be formed in subsequent processes. Therefore, a laser drilling process that is used to fabricate the conductive layers on the dielectric bodies is not required, and the fabrication cost is reduced.

### BRIEF DESCRIPTION OF THE DRAWINGS

FIGS. 1A-1C are schematic cross-sectional views showing a method of fabricating a conventional package structure;

FIGS. 2A-2E are schematic cross-sectional views showing a method of fabricating a package structure of a first embodiment according to the present invention, wherein FIGS. 2B′ and 2B″ are different embodiments of FIG. 2B, and FIG. 2E′ is another embodiment of FIG. 2E;

FIGS. 3A-3D are schematic cross-sectional views showing a method of fabricating a package structure of a second embodiment according to the present invention; and

FIGS. 4A-4E are schematic cross-sectional views showing a method of fabricating a package structure of a third embodiment according to the present invention.

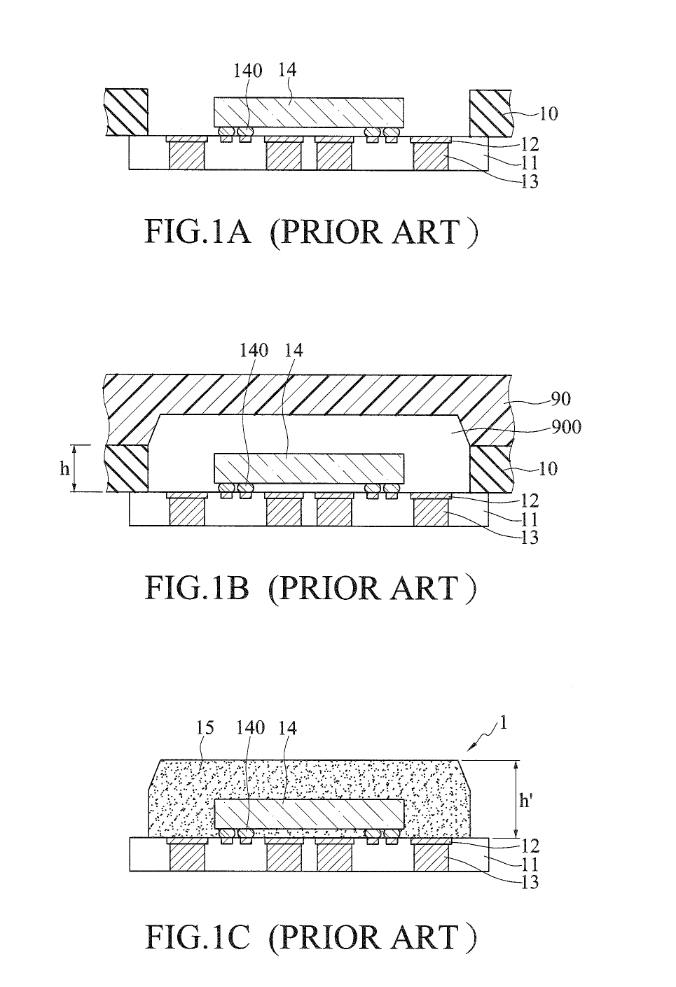

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms such as “upper” “one” are merely for illustrative purpose and should not be construed to limit the scope of the present invention.

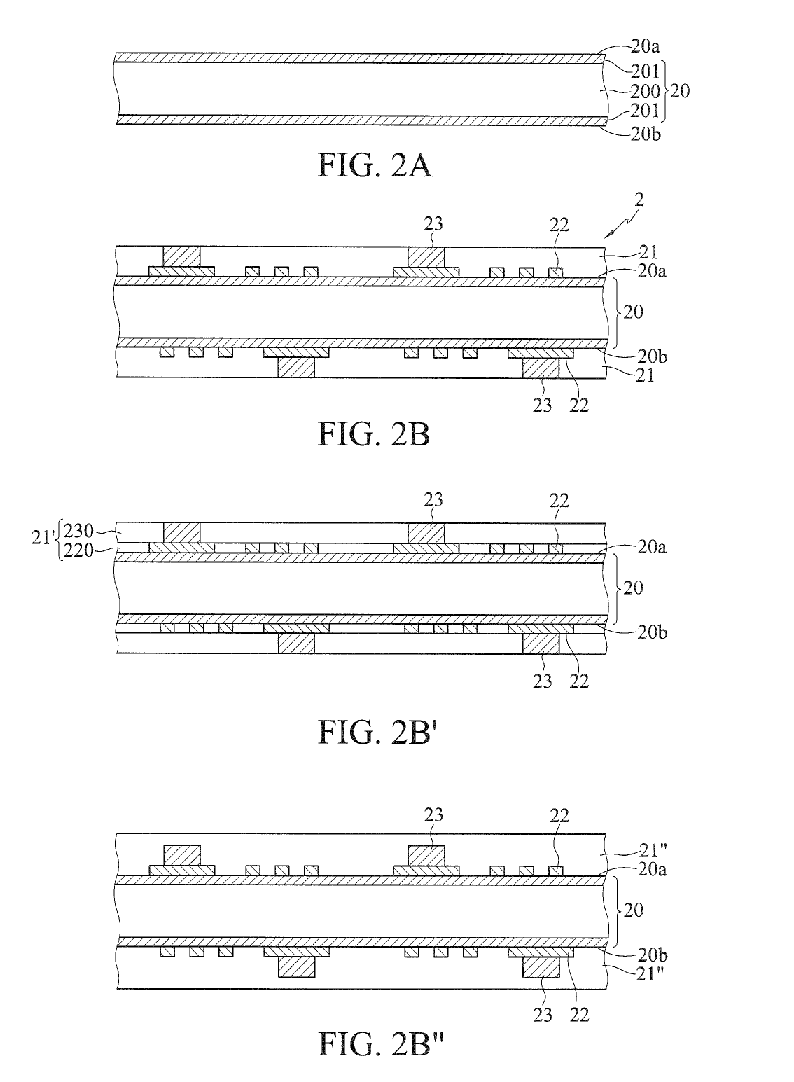

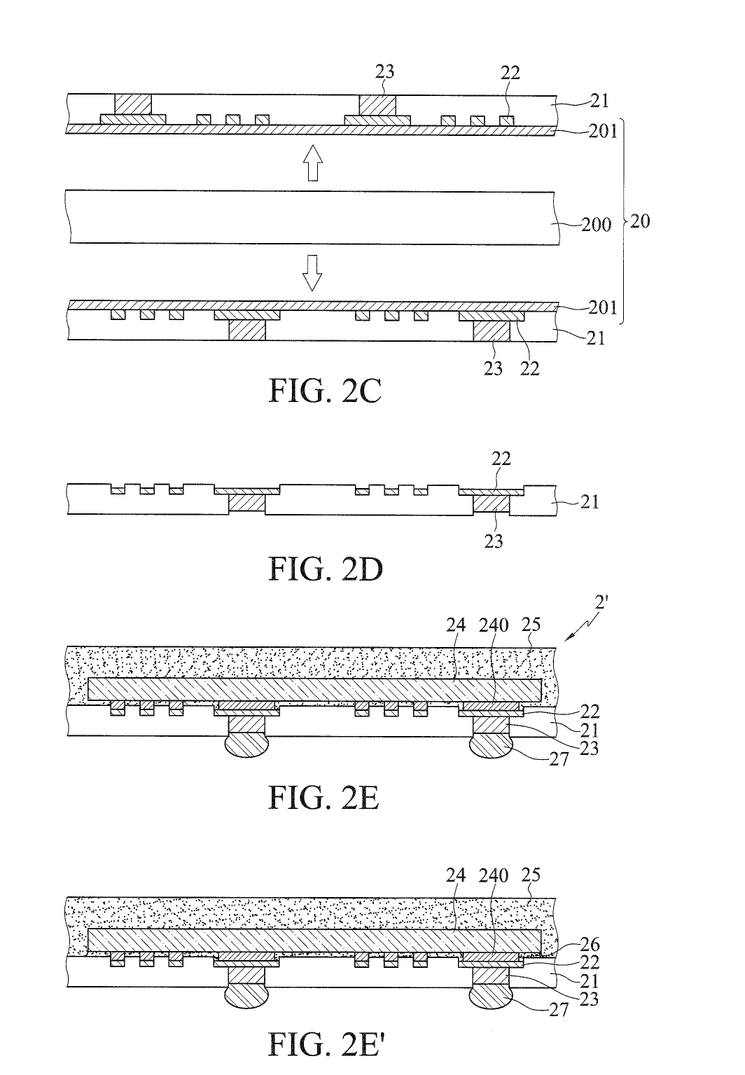

FIGS. 2A-2E are schematic cross-sectional views showing a method of fabricating a package structure 2 of a first embodiment according to the present invention.

As shown in FIG. 2A, a carrier 20 having two opposing surfaces 20a and 20b is provided.

In an embodiment, the two surfaces 20a and 20b of the carrier 20 are metal surfaces. In another embodiment, the carrier 20 has a board 200 such as a metal board, a semiconductor wafer or a glass board, and a metal layer 201 is formed on two opposing sides of the board 200. The metal layer 201 is a copper foil. In yet another embodiment, a release film, an adhesive or an insulating material can be disposed between the board 200 and the metal layer 201 according to practical requirements, so as to facilitate the latter separation process.

As shown in FIG. 2B, two dielectric bodies 21 are formed on the two surfaces 20a and 20b of the carrier 20, respectively, and each of the dielectric bodies 21 has a first wiring layer 22 embedded therein and a first conductive layer 23 formed on a portion of a surface of the first wiring layer 22.

In an embodiment, the dielectric bodies 21 are made of, but not limited to a molding compound, a prepreg, or a photosensitive dielectric layer. In an embodiment, the dielectric bodies 21, the first wiring layers 22 and the first conductive layers 23 can be fabricated in any order.

In an embodiment, the first wiring layers 22 are formed on the two surfaces 20a and 20b of the carrier 20 via a first resist layer, then first conductive layers 23 are formed on a portion of the surfaces of the first wiring layers 22 through a second resist layer, the first resist layer and second resist layer are removed, and the dielectric bodies 21 are formed on the two surfaces 20a and 20b of the carrier 20 by a molding or lamination process.

In another embodiment, the first wiring layers 22 are formed on the two surfaces 20a and 20b of the carrier 20 through a first photosensitive dielectric layer 220, and the first conductive layers 23 are then formed on a portion of the surfaces of the first wiring layers 22 through a second photosensitive dielectric layer 230, with the first and second photosensitive dielectric layers 220 and 230 serving as the dielectric bodies 21′, as shown in FIG. 2B′.

In an embodiment, the first conductive layers 23 are exposed from the surfaces of the dielectric bodies 21. In another embodiment, the dielectric bodies 21″ are formed on the two surfaces 20a and 20b of the carrier 20 by a molding or lamination process, as shown in FIG. 2B″. The first conductive layers 23 are not exposed from the surfaces of the dielectric bodies 21″. A grinding method is then performed to remove a portion of an upper surface of the dielectric body 21″, with the first conductive layer 23 exposed from the surface of the dielectric body 21. Alternatively, the dielectric body 21 can be directly formed, as shown in FIG. 2B.

In an embodiment, the first wiring layers 22 are coupled to the two surfaces 20a and 20b of the carrier 20, respectively.

As shown in FIG. 2C, the board 200 of the carrier 20 is removed by using a conventional separation method.

As shown in FIG. 2D, the metal layers 201 on the dielectric bodies 21 are etched, until the surfaces of the first wiring layers 22 are lower than the dielectric bodies 21.

In an embodiment, at the time the metal layers 201 are etched, the surfaces of the first conductive layers 23 are also etched, until the surfaces of the first conductive layers 23 are lower than the dielectric bodies 21.

As shown in FIG. 2E, at least one electronic component 24 is disposed on one of the dielectric bodies 21, and electrically connected with one of the first wiring layers 22.

In an embodiment, an encapsulant 25 is formed on the one of the dielectric bodies 21, and encapsulates the electronic component 24.

In an embodiment, the electronic component 24 is an active component, a passive component, or a combination of thereof. In another embodiment, the active component is a semiconductor chip, and the passive component is a resistor, a capacitor or an inductor.

Further, the electronic component 24 is electrically connected to the first wiring layer 22 via a plurality of conductive elements 240 such as solder materials and copper pillars, and the conductive element 240 is encapsulated by the encapsulant 25. In another embodiment, the electronic component 24 is electrically connected to the first wiring layer 22 through wire bonding.

In an embodiment, a plurality of conductive elements 27 such as solder materials are formed on the first conductive layers 23.

In another embodiment, as shown in FIG. 2E′, an underfill 26 is filled into the space between the dielectric body 21 and the electronic component 24, so as to encapsulate the conductive elements 240 and securely fix the electronic component 24 in position. An encapsulant 25 is formed on the dielectric body 21, and encapsulates the electronic component 24 and the underfill 26.

The method of fabricating a package structure according to the present invention is characterized by forming the first wiring layers 22, the first conductive layers 23 and the dielectric bodies 21 or 21′ independently on the two opposing surfaces of the carrier, as compared with the prior art, which forms these components on only one side of the carrier. Hence, the production yield of the package structure thus fabricated according to the present invention is increased by two fold, as compared with the prior art, and the present invention has the advantage of increasing production yield.

Moreover, the carrier 20 is removed to prevent forming the conventional supporting board, such that the cavity of the mold can be reduced according to practical needs when forming the encapsulant 25, thereby greatly reducing the structural height of the package structure 2′. As a result, the package structure 2′ according to the present invention is capable of satisfying the low-profile requirement for electronic products.

In a method according to the present invention, the first wiring layers 22 and the first conductive layers 23 are formed first, the dielectric bodies 21 are then formed, and then the conductive layers are exposed to be electrically connected to circuits that are to be formed in subsequent processes. Therefore, a laser drilling process that is used to fabricate the conductive layers 23 on dielectric bodies 21 is not required, and the fabrication cost is reduced.

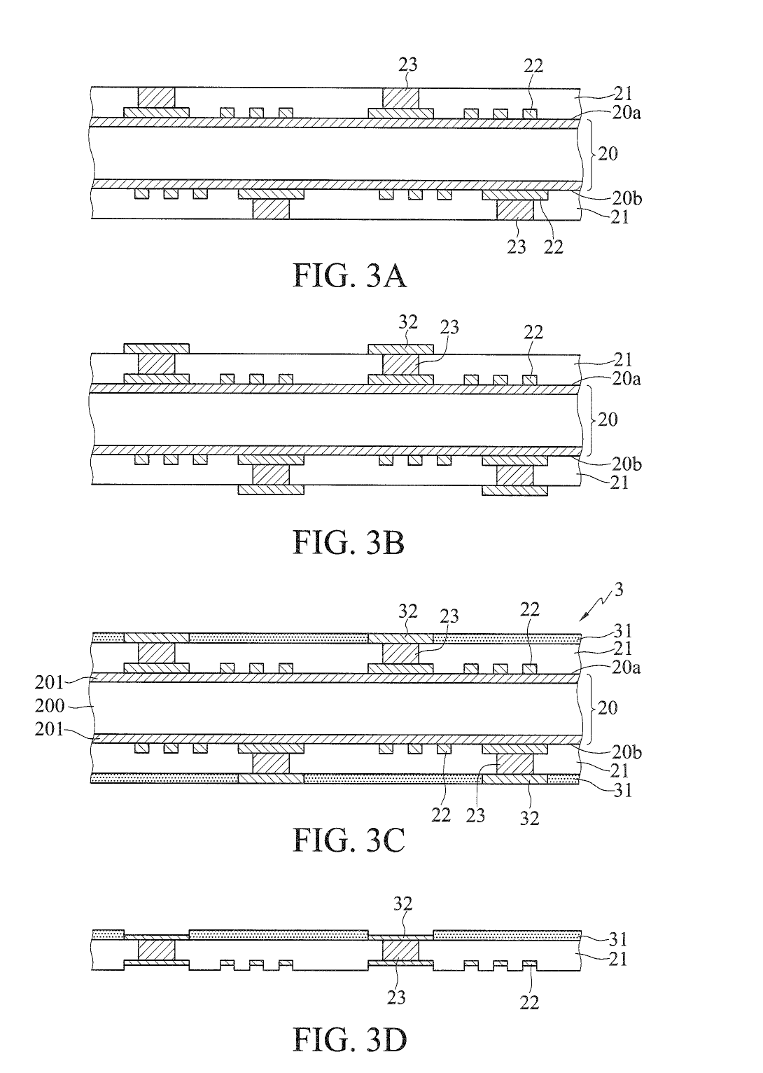

FIGS. 3A-3D are schematic cross-sectional views showing a method of fabricating a package structure 3 of a second embodiment according to the present invention.

As shown in FIG. 3A, a structure similar to the structure shown in FIG. 2B is provided.

In the second embodiment, the structure of FIG. 3A can be fabricated according to the processes shown in FIGS. 2A and 2B.

As shown in FIG. 3B, second wiring layers 32 are formed on the dielectric bodies 21 by a patterning process, and are electrically connected to the first conductive layers 23.

As shown in FIG. 3C, insulation protection layers 31 on the dielectric bodies 21 and the second wiring layers 32.

In an embodiment, the second wiring layers 32 are exposed from surfaces of the insulation protection layers 31. In fabrication, the insulation protection layers 31 are pressed on the dielectric bodies 21, with the second wiring layers 32 free from being exposed from the surfaces of the insulation protection layers 31, and a portion of upper surfaces of the insulation protection layers is ground and removed, with the surfaces of the second wiring layers 32 flush with the surfaces of the insulation protection layers 31 and the second wiring layers 32 exposed from the surfaces of the insulation protection layers 31.

As shown in FIG. 3D, the board 200 of the carrier 20 is removed by using a conventional separation process, and the metal layer 201 on the dielectric bodies 21 is etched and removed, until the surfaces of the first wiring layers 22 are lower than the dielectric bodies 21.

In an embodiment, at the time the metal layers 201 are etched, the surfaces of the second conductive layers 32 are also etched, until the surfaces of the second wiring layers 32 are lower than the insulation protection layers 31.

In a method according to the present invention, the first wiring layers 22 and the first conductive layers 23 are formed first, the dielectric bodies 21 are then formed, and then the first conductive layers 23 are exposed to be electrically connected to the second wiring layers 32. Therefore, a laser drilling process that is used to fabricate the first conductive layers 23 on the dielectric bodies 21 is not required, and the fabrication cost is reduced.

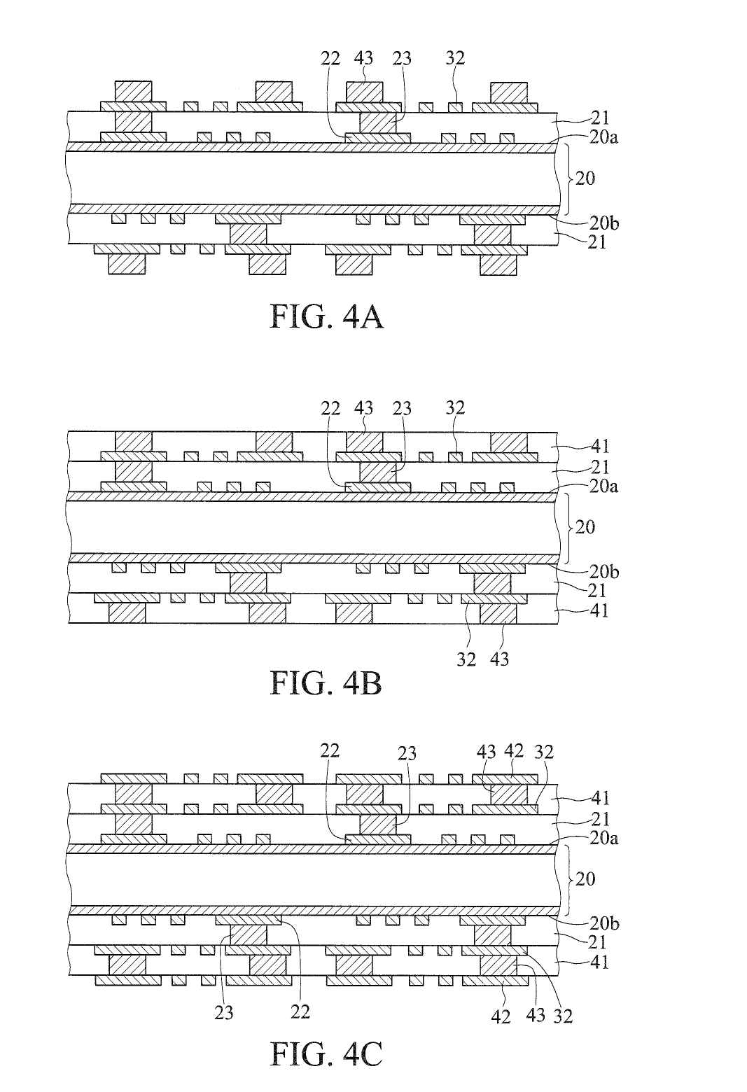

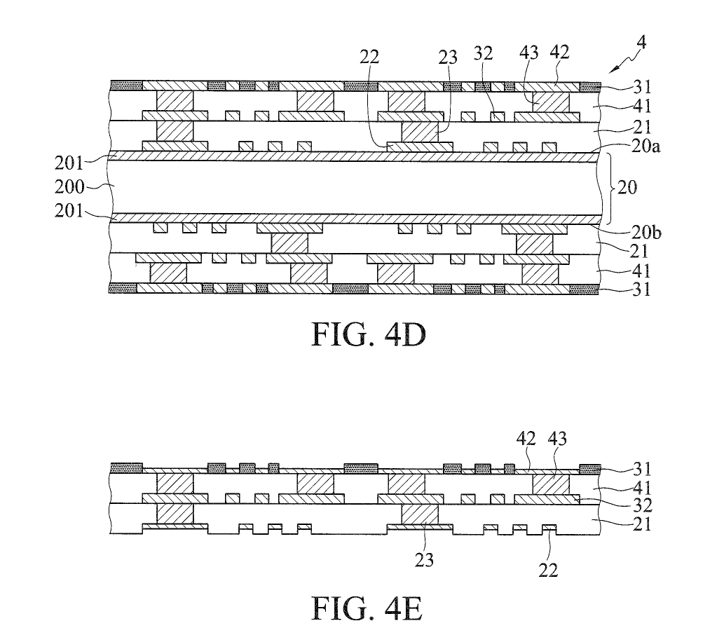

FIGS. 4A-4E are schematic cross-sectional views showing a method of fabricating a package structure 4 of a third embodiment according to the present invention.

As shown in FIG. 4A, the process thereof subsequent to the process shown in FIG. 2B, second wiring layers 32 are formed on the dielectric bodies 21 and electrically connected to the first conductive layers 23, and second conductive layers 43 are formed on a portion of surfaces of the second wiring layers 32.

In an embodiment, the second wiring layers 32 are formed on the dielectric bodies via a first resist layer, the second conductive layers 43 are then formed on the portion of the surfaces of the second wiring layers 32 via a second resist layer, and finally the first and second resist layers are removed.

As shown in FIG. 4B, dielectric layers 41 are formed on the dielectric bodies 21, and encapsulate the second wiring layers 32 and the second conductive layers 43.

In an embodiment, the dielectric layers 41 are made of, but not limited to a molding compound, a prepreg, or a photosensitive dielectric layer, and the dielectric layers 41 and the dielectric bodies 21 can be made of the same or different materials.

In an embodiment, the dielectric layers 41 are formed on the dielectric bodies 21 by a molding or pressing process. In another embodiment, the dielectric layers 41 are formed according to the processes shown in FIG. 2B′.

The second conductive layers 43 are exposed from surfaces of the dielectric layers 41. For example, the dielectric layers 41 are formed according to the processes shown in FIG. 2B″, or have an aspect the same as the dielectric layers 41 shown in FIG. 4B.

The dielectric layers 41, the second wiring layer 32 and the second conductive layer 43 are formed in any order.

As shown in FIG. 4C, third wiring layers 42 are formed on the dielectric layers 41 by a patterning process, and electrically connected to the second conductive layers 43.

As shown in FIG. 4D, insulation protection layers 31 are formed on the dielectric layers 41 and the third wiring layers 42.

In an embodiment, the third wiring layers 42 are exposed from surfaces of the insulation protection layers 31. In fabrication, the insulation protection layers 31 are pressed on the dielectric bodies 41, with the third wiring layers 42 free from being exposed from the surfaces of the insulation protection layers 31, and a portion of upper surfaces of the insulation protection layers is ground and removed, with the surfaces of the third wiring layers 42 flush with the surfaces of the insulation protection layers 31 and the third wiring layers 42 exposed from the surfaces of the insulation protection layers 31.

As shown in FIG. 4E, the board 200 of the carrier 20 is removed by using a conventional separation process, and the metal layer 201 on the dielectric bodies 21 is etched and removed, until the surfaces of the first wiring layers 22 are lower than the dielectric bodies 21.

In an embodiment, at the time the metal layers 201 are etched, the surfaces of the third conductive layers 42 are also etched, until the surfaces of the third wiring layers 32 are lower than the insulation protection layers 31.

In a method according to the present invention, the second wiring layers 32 and the second conductive layers 43 are formed first, the dielectric bodies 41 are then formed, and then the second conductive layers 43 are exposed to be electrically connected to the third wiring layers 42. Therefore, a laser drilling process that is used to fabricate the second conductive layers 43 on the dielectric bodies 41 is not required, and the fabrication cost is reduced.

The present invention provides a package structure 2, 3, 4, comprising: a carrier 20 having two opposing surfaces 20a and 20b, and two dielectric bodies 21 or 21′ formed on the two surfaces 20a and 20b of the carrier 20, respectively.

Each of the dielectric bodies 21 and 21′ has a first wiring layer 22 embedded therein and a first conductive layer 23 formed on the first wiring layer 22.

In an embodiment, the two surfaces of the carrier 20 are metal surfaces.

In an embodiment, the first wiring layers 22 are coupled to the carrier 20.

In an embodiment, the first conductive layers 23 are exposed from the dielectric bodies 21 and 21′.

In an embodiment, the dielectric bodies 21 and 21′ are made of a molding compound, a prepregs, or a photosensitive dielectric layer.

In an embodiment, the package structure 3, 4 further comprises a second wiring layer 32 formed on the dielectric bodies 21 and electrically connected to the first conductive layer 23.

In an embodiment, the package structure 3 further comprises an insulation protection layer 31 formed on the dielectric bodies 21 and the second wiring layer 32.

Alternatively, the package structure 4 further comprises a second conductive layer 43 formed on the second wiring layer 32, and a dielectric layer 41 formed on the dielectric bodies 21 and encapsulating the second wiring layer 32 and the second conductive layer 43. The package structure 4 further comprises a third wiring layer 42 formed on the dielectric layer 41 and electrically connected to the second conductive layer 43, and an insulation protection layer 31 formed on the dielectric layer 41 and the third wiring layer 42.

In summary, the package structure and the method of fabricating the package structure according to the present invention are characterized by forming the wiring layers, the conductive layers and the dielectric bodies on two opposing surfaces of the carrier independently, as compared with the prior art, which forms these components on only one side of the carrier. Hence, the production yield of the package substrate thus fabricated according to present invention is increased by two fold, as compared to the prior art, and the present invention has the advantage of increasing production yield.

Moreover, the carrier is removed to prevent forming the conventional supporting board, such that the cavity of the mold can be reduced according to practical needs when forming the encapsulant, thereby greatly reducing the structural height of the package and satisfying the low-profile requirement for electronic products.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A package structure, comprising:
a carrier having two opposing surfaces; and
two dielectric bodies formed on the two surfaces of the carrier, respectively, each of the dielectric bodies having a first wiring layer embedded therein and a first conductive layer formed on the first wiring layer.

2. The package structure of claim 1, wherein the two surfaces of the carrier are metal surfaces.

3. The package structure of claim 1, wherein the first wiring layers are coupled to the carrier.

4. The package structure of claim 1, wherein the first conductive layers are exposed from the dielectric bodies.

5. The package structure of claim 1, wherein the dielectric bodies are made of a molding compound, a prepreg, or a photosensitive dielectric layer.

6. The package structure of claim 1, further comprising second wiring layers formed on the dielectric bodies and electrically connected to the first conductive layers.

7. The package structure of claim 6, further comprising insulation protection layers formed on the dielectric bodies and the second wiring layers.

8. The package structure of claim 6, further comprising second conductive layers formed on the second wiring layers, and dielectric layers formed on the dielectric bodies and encapsulating the second wiring layers and the second conductive layers.

9. The package structure of claim 8, further comprising third wiring layers formed on the dielectric layers and electrically connected to the second conductive layers.

10. The package structure of claim 9, further comprising forming insulation protection layers on the dielectric layers and the third wiring layers.

11. A method of fabricating a package structure, comprising:
providing a carrier having two opposing surfaces;
forming dielectric bodies on the two surfaces of the carrier, respectively, each of the dielectric bodies having a first wiring layer embedded therein and a first conductive layer formed on the first wiring layer; and
removing the carrier.

12. The method of claim 11, wherein the two surfaces of the carrier are metal surfaces.

13. The method of claim 11, wherein the first wiring layers are firstly formed on the two surfaces of the carrier, the first conductive layers are then formed on a portion of the surfaces of the first wiring layers, and the dielectric bodies are then formed on the two surfaces of the carrier.

14. The method of claim 11, wherein the first wiring layers are formed on the two surfaces of the carrier through first photosensitive dielectric layers, and the first conductive layers are then formed on a portion of the two surfaces of the first wiring layers through second photosensitive dielectric layers, with the first and second photosensitive dielectric layers serving as the dielectric bodies.

15. The method of claim 11, wherein the first conductive layers are exposed from the dielectric bodies.

16. The method of claim 15, wherein the dielectric bodies are formed on the two surfaces of the carrier, the first conductive layers are free from being exposed from the two surfaces of the dielectric bodies, and a portion of the surfaces of dielectric bodies is then removed, with the first conductive layers exposed from the dielectric bodies.

17. The method of claim 11, wherein the dielectric bodies are made of a molding compound, a prepreg, or a photosensitive dielectric layer.

18. The method of claim 11, further comprising disposing an electronic component on the dielectric bodies, and electrically connecting the electronic component to the first wiring layers.

19. The method of claim 18, further comprising forming on the dielectric bodies encapsulant that encapsulates the electronic component.

20. The method of claim 18, further comprising filling an underfill into the space between the dielectric bodies and the electronic component in order to securely fix the electronic component in position.

21. The method of claim 11, further comprising forming on the dielectric bodies second wiring layers that are electrically connected to the first conductive layer.

22. The method of claim 21, further comprising forming insulation protection layers on the dielectric bodies and the second wiring layers.

23. The method of claim 21, further comprising forming second conductive layers on the second wiring layers, and forming on the dielectric bodies dielectric layers that encapsulate the second wiring layers and the second conductive layers.

24. The method of claim 23, further comprising forming on the dielectric layers third wiring layers that are electrically connected to the second conductive layers.

25. The method of claim 24, further comprising forming insulation protection layers on the dielectric layers and the third wiring layers.
